(19) United States
(12) Patent Application Publication
(10) Pub. No.: US 2023/0380170 A1
(43) Pub. Date: Nov. 23, 2023

(54) EPITAXIAL SILICON CHANNEL GROWTH

(71) Applicant: Applied Materials, Inc., Santa Clara, CA (US)

(72) Inventors: Hsiang Yu Lee, Cupertino, CA (US); Pradeep K. Subrahmanyan, San Jose, CA (US)

(73) Assignee: Applied Materials, Inc., Santa Clara, CA (US)

(21) Appl. No.: 18/319,876

(22) Filed: May 18, 2023

Related U.S. Application Data
(60) Provisional application No. 63/343,437, filed on May 18, 2022.
(60) Provisional application No. 63/409,697, filed on Sep. 23, 2022.

(51) Int. Cl. H10B 43/35; C30B 29/06; C30B 29/16; C30B 29/38; C30B 29/68; C30B 33/08; H10B 43/10; H10B 43/27

(52) U.S. Cl. CPC H10B 43/35; C30B 29/06; C30B 29/16; C30B 29/38; C30B 29/68; C30B 33/08; H10B 43/10; H10B 43/27

(57) ABSTRACT

A three-dimensional NAND flash memory structure may include solid channel cores of epitaxial silicon that are grown directly from a silicon substrate reference. The alternating oxide-nitride material layers may be formed as a stack, and a channel hole may be etched through the material layers that extends down to the silicon substrate. A tunneling layer may be formed around the channel hole to contact the alternating material layers, and an epitaxial silicon core may be grown from the silicon substrate up through the channel holes. In some implementations, support structures may be formed in channel holes or in slits of the memory array to provide physical support while the epitaxial silicon cores are grown through the channels.

### CROSS-REFERENCE TO RELATED APPLICATIONS

This application claims priority to U.S. Provisional Patent Application 63/409,697, filed Sep. 23, 2022, and entitled “EPITAXIAL SILICON CHANNEL GROWTH,” which is incorporated herein by reference. This application also claims priority to U.S. Provisional Patent Application 63/343,437, filed May 18, 2022, and entitled “EPITAXIAL SILICON CHANNEL GROWTH,” which is incorporated herein by reference.

### TECHNICAL FIELD

This disclosure generally describes memory cells with epitaxial silicon channel cores. More specifically, this disclosure describes techniques for fabricating 3D NAND flash memory structures with epitaxial channel cores grown from a silicon substrate.

### BACKGROUND

A memory design known as NAND memory is a non-volatile flash memory storage architecture that does not require power to maintain its stored data. NAND flash memory is used in many products, such as solid-state devices and portable electronics. In order to improve the density and reduce the size of NAND memories, traditional two-dimensional NAND architectures have transitioned to three-dimensional NAND stacks. Unlike 2D planar NAND technologies where the individual memory cells are stacked together on separate horizontal substrates, 3D NAND is stacked vertically using multiple layers of alternating conducting and dielectric materials with intersecting vertical channels.

### SUMMARY

In some embodiments, a three-dimensional (3D) NAND memory structure may include a silicon substrate and a plurality of alternating material layers arranged in a vertical stack on the silicon substrate. A channel hole may extend through the plurality of alternating material layers to the silicon substrate, and the channel hole may be perpendicular to the plurality of alternating material layers. The memory structure may also include a channel inside the channel hole that may include a tunneling layer around an interior of the channel hole contacting the plurality of alternating material layers and an epitaxial silicon core inside the tunneling layer that contacts the silicon substrate.

In some embodiments, a method of fabricating a 3D NAND memory structure may include forming a plurality of alternating material layers arranged in a vertical stack on a silicon substrate; etching a channel hole that extends through the plurality of alternating material layers to the silicon substrate; forming a tunneling layer around the channel hole contacting the plurality of alternating material layers; and epitaxially growing an epitaxial silicon core from the silicon substrate through the channel hole inside of the tunneling layer.

In some embodiments, a 3D NAND memory array may include a silicon substrate and a plurality of alternating material layers arranged in a vertical stack on the silicon substrate. A plurality of channel holes may extend through the plurality of alternating material layers. The memory array may also include a plurality of support structures that extend through the plurality of alternating material layers into the silicon substrate.

In some embodiments, a 3D NAND memory structure may include a layer on a silicon substrate and an oxide layer over the silicon substrate. A hole may be etched through the oxide layer to expose the silicon substrate. The structure may also include epitaxial silicon that is grown from the substrate through the hole in the oxide layer, and a nitride layer that covers the oxide layer and the epitaxial silicon.

In some embodiments, a method of fabricating a 3D NAND memory structure may include forming a layer on a silicon substrate. The method may also include etching a hole that extends through the layer to expose the silicon substrate. The method may additionally include epitaxially growing epitaxial silicon for a channel from the silicon substrate through the hole. The method may further include forming the 3D NAND memory structure over the layer and the substrate such that a channel hole in the 3D NAND memory structure comprises an epitaxial silicon core grown from the epitaxial silicon.

In any embodiments, any and all of the following features may be implemented in any combination and without limitation. The silicon substrate may include a single-crystal silicon from which the epitaxial silicon core is grown through the channel hole. The alternating material layers may include alternating layers of an oxide material and a nitride material. The alternating material layers may include alternating layers of an oxide material and a metal, where the metal may form a gate electrode for individual memory cells in the memory structure. The epitaxial silicon core may extend into the silicon substrate. The memory structure may also include a layer of epitaxial silicon that extends beyond the channel hole, where the layer of epitaxial silicon may be between the silicon substrate and the plurality of alternating material layers, and the layer of epitaxial silicon may connect the epitaxial silicon core to a plurality of other channels in the memory structure. The memory structure may also include a support structure that extends through the plurality of alternating material layers and the layer of epitaxial silicon and extends into the silicon substrate. A slit may be etched in the memory structure that extends through the plurality of alternating material layers into a sacrificial nitride layer that is above the silicon substrate. The sacrificial nitride layer may be exposed to an etch process that is configured to selectively etch the sacrificial nitride layer. A portion of the tunneling layer may be removed that is exposed after removing the sacrificial nitride layer. An epitaxial silicon layer may be epitaxially grown from the silicon substrate to replace the sacrificial nitride layer. A second channel hole may be etched that extends through the plurality of alternating material layers into the silicon substrate, and the second channel hole may be filled with a gap fill material as a support structure. The plurality of support structures may include a metal that fills one or more of the plurality of channel holes. The plurality of support structures may include a gap-fill material in a slit in the memory array. Alternating slits in the memory array may form the support structures. The plurality of support structures may include a combination of a gap-fill material in one or more slits in the memory array and/or a metal that fills one or more of the plurality of channel holes.

When an epitaxial silicon plug is instead formed before the alternating material layers, such as growing epitaxial silicon above the top surface of a silicon oxide layer above the silicon substrate, the 3D NAND memory structure may be formed on top of the epitaxial silicon. For example, the method may also include forming a nitride layer over the layer and the epitaxial silicon and polishing the nitride layer to remove surface variations caused by a difference in height between the layer and the epitaxial silicon. The method may further include forming a plurality of alternating nitride and oxide layers over the layer and the substrate; etching a channel hole through the plurality of alternating nitride and oxide layers to expose the epitaxial silicon; and epitaxially growing the epitaxial silicon up through the channel hole to form the epitaxial silicon core of the channel hole. The epitaxial silicon may extend above a top surface of the oxide layer. A top surface of the nitride layer may be planarized such that the top surface of the nitride layer is flat without surface variations caused by a difference in height between the oxide layer and the epitaxial silicon. The hole may extend below a top surface of the silicon substrate such that the epitaxial silicon extends into the silicon substrate. A plurality of alternating material layers arranged in a vertical stack on the nitride layer. A channel hole may extends through the plurality of alternating material layers to the epitaxial silicon.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a top plan view of one embodiment of a processing system of deposition, etching, baking, and curing chambers according to some embodiments.

FIGS. 2A-2Q illustrate incremental stages for generating an array of 3D NAND flash memory cells with epitaxial silicon channels, according to some embodiments.

FIG. 3A illustrates a portion of a memory array, according to some embodiments.

FIG. 3B illustrates a portion of a memory array when the some of the channels have been used for support structures to facilitate the epitaxial silicon channel cores, according to some embodiments.

FIGS. 4A-4L illustrate incremental steps in a fabrication process for a memory structure that use the slits that separate the memory blocks for support structures when growing the epitaxial silicon channels for the individual memory cells, according to some embodiments.

FIG. 5 illustrates a top view of a portion of a memory array, according to some embodiments.

FIGS. 6A-61I illustrate incremental steps for forming a stack that includes support structures in both channel holes and slits, according to some embodiments.

FIG. 7 illustrates a top view of a portion of a memory array, according to some embodiments.

FIG. 8 illustrates a flowchart of a method for fabricating a 3D NAND memory structure, according to some embodiments.

FIGS. 9A-9I illustrate steps in a process for forming channel holes with epitaxial silicon at the base of the channel holes before the channel holes are formed in the tiers of alternating oxide/nitride layers, according to some embodiments.

FIG. 10 illustrates a flowchart 1000 of a method for fabricating a 3D NAND memory structure, according to some embodiments.

### DETAILED DESCRIPTION

Traditional three-dimensional (3D) NAND flash memory structures use channel cores made from oxide materials or polysilicon. However, epitaxial silicon exhibits a much higher mobility than polysilicon or other similar materials. This disclosure describes a 3D NAND flash memory structure using epitaxial silicon cores that are grown directly from a silicon substrate reference. The alternating oxide-nitride material layers may be formed as a stack, and a channel hole may be etched through the material layers that extends down to the silicon substrate. A tunneling layer may be formed around the channel hole to contact the alternating material layers, and an epitaxial silicon core may be grown from the silicon substrate up through the channel holes. In some implementations, support structures may be formed in channel holes or in slits of the memory array to provide physical support while the epitaxial silicon cores are grown through the channels.

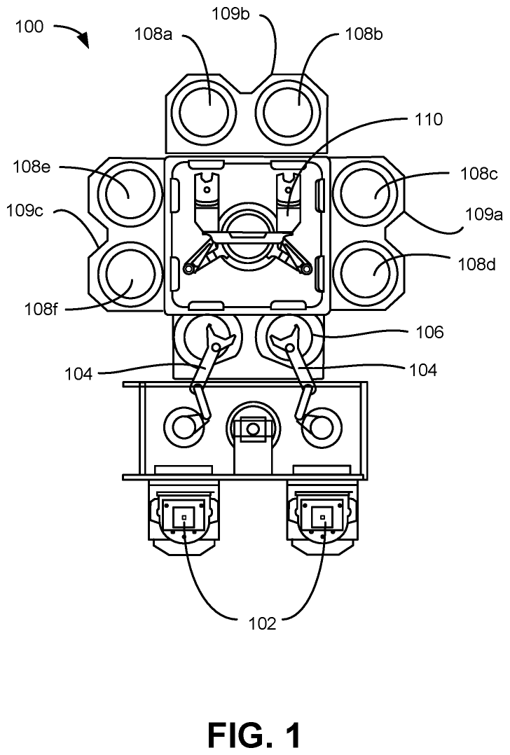

FIG. 1 illustrates a top plan view of one embodiment of a processing system 100 of deposition, etching, baking, and curing chambers according to some embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by the processing system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

The processing system 100, or more specifically chambers incorporated into the processing system 100 or other processing systems, may be used to produce structures according to some embodiments of the present technology. For example, the processing system 100 may be used to produce memory arrays by performing operations such as deposition, etch, sputtering, polishing, cleaning, and so forth, in the various substrate processing chambers 108.

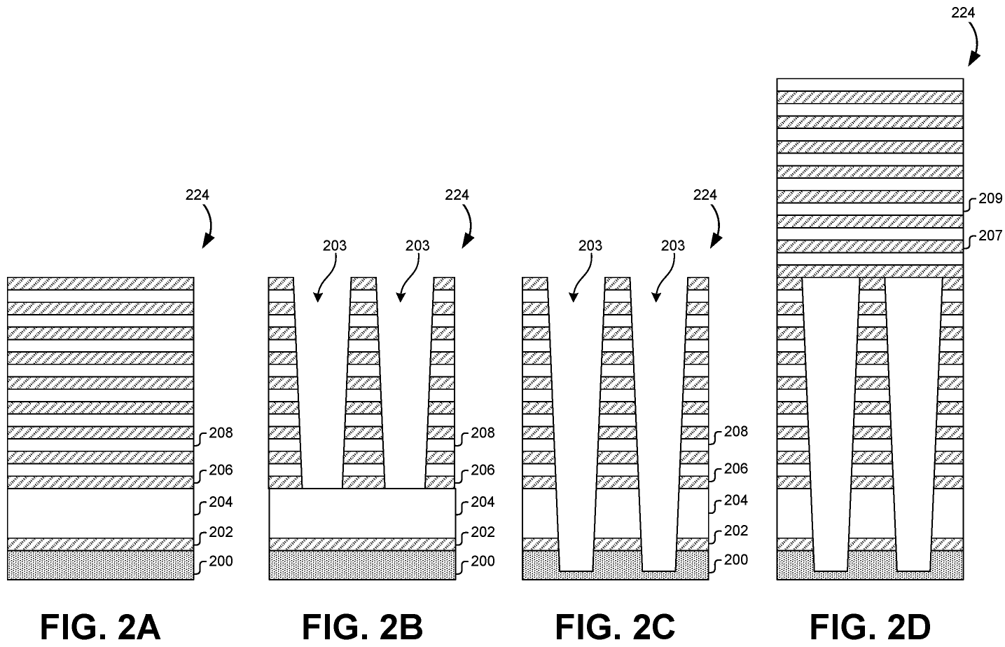

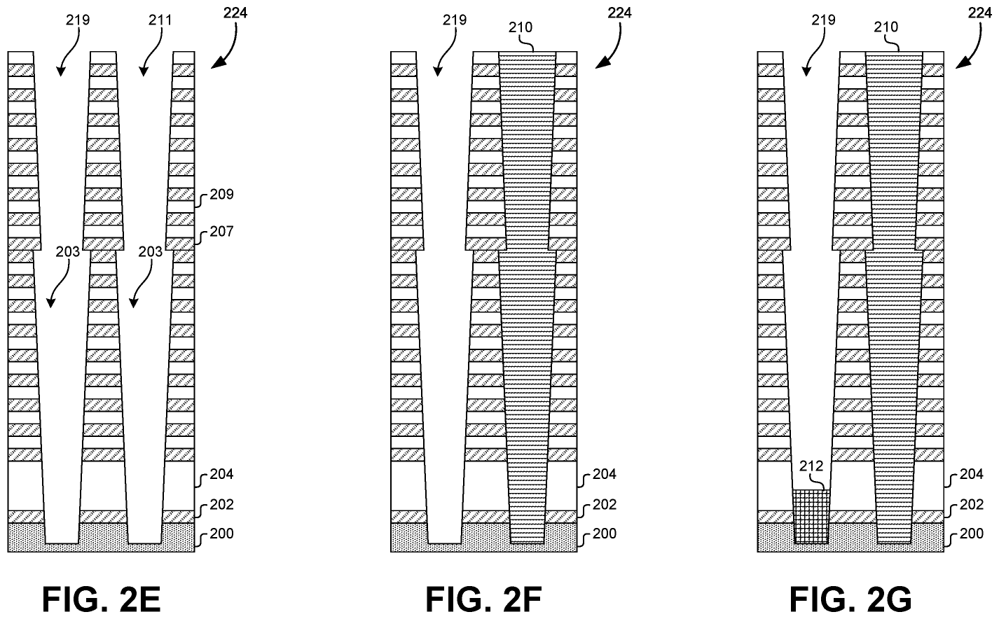

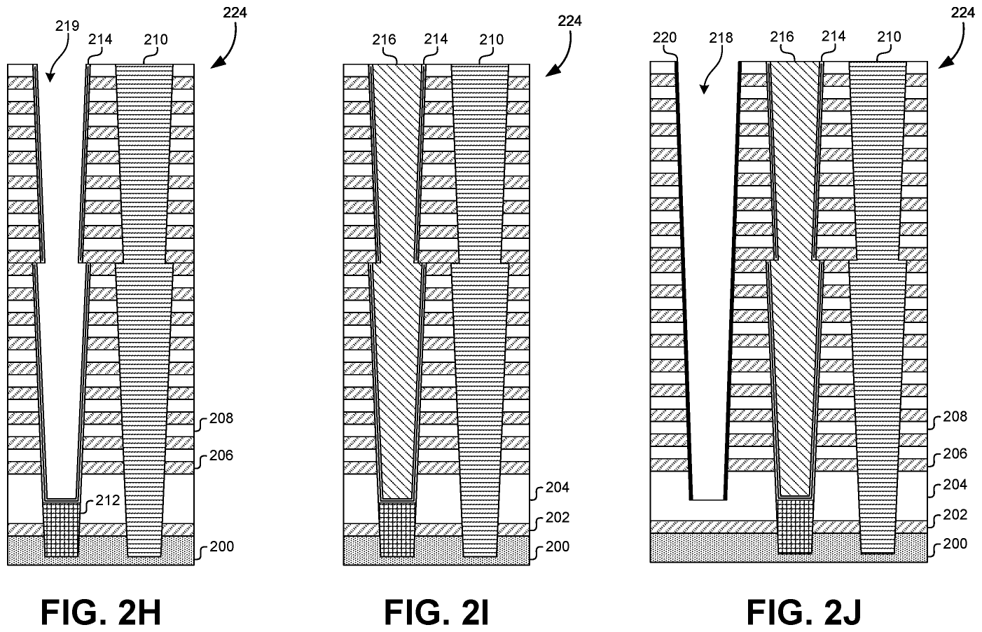

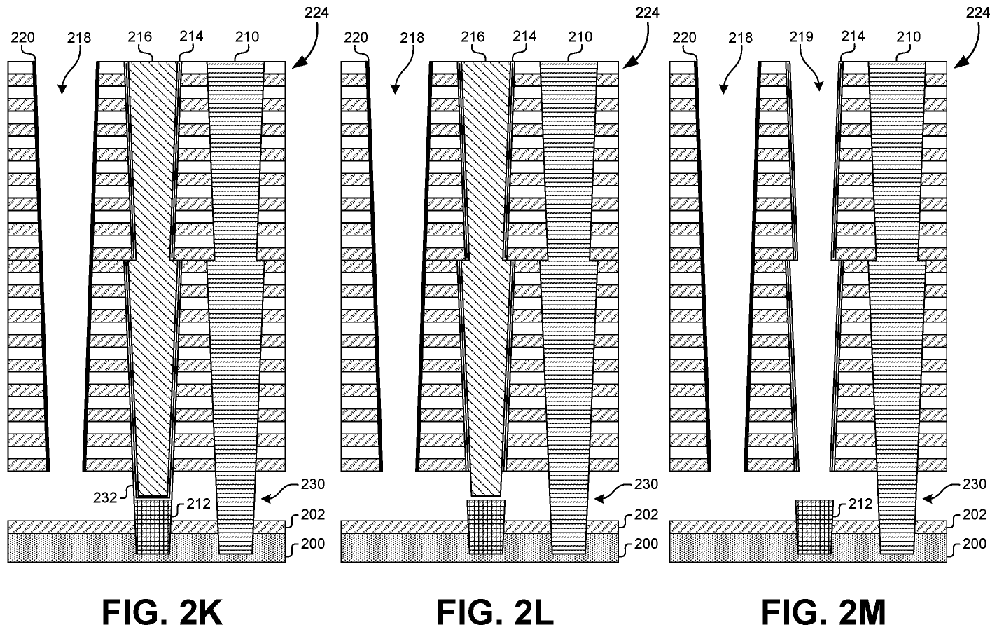

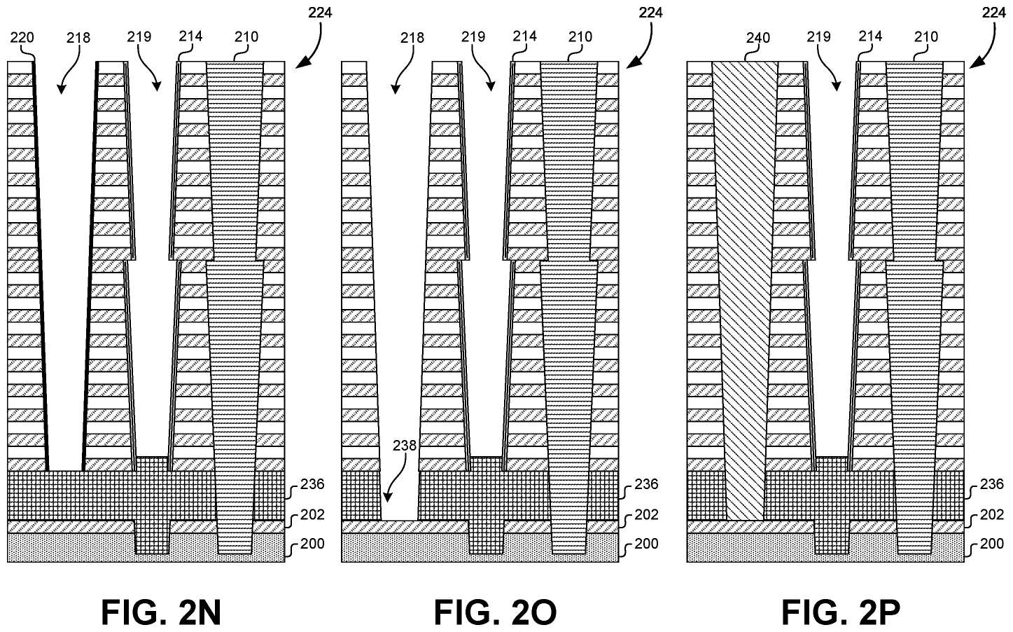

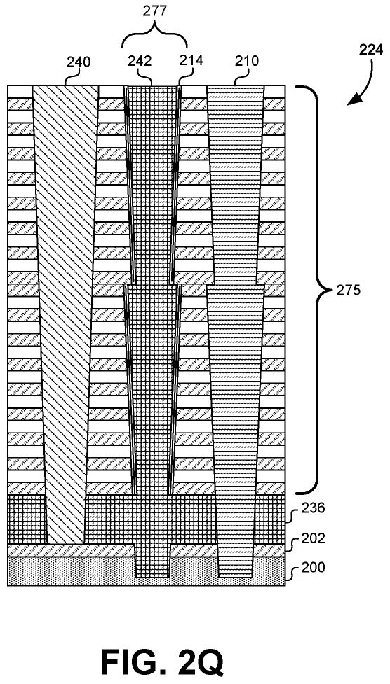

FIGS. 2A-2Q illustrate incremental stages for generating an array of 3D NAND flash memory cells with epitaxial silicon channels, according to some embodiments. FIG. 2A illustrates a partial stack of alternating oxide-nitride layers that may be formed for the 3D NAND flash array. Each of the layers illustrated in FIG. 2A may be formed incrementally, one layer on top of the previous layer using any deposition or layer formation techniques. In this example, the layers may be formed on a substrate 200 of a silicon material, such as a epitaxial silicon or a single-crystal silicon wafer. A silicon oxide layer 202 may be formed over the substrate 200, followed by a silicon nitride layer 204. In some embodiments, the silicon oxide layer 202 and the silicon nitride layer 204 may represent initial layers on the substrate 200, and these layers may be thicker than the alternating oxide-nitride layers formed thereon. Next, alternating layers of silicon oxide 206 and silicon nitride 208 may be formed in a stack.

The progressive formation of the substrate 200, silicon oxide layers 206, silicon nitride layers 208, and other materials described below in FIGS. 2A-2Q may be collectively referred to as a stack 224. As illustrated in FIG. 2A, the stack 224 may initially be of a limited height. For example, the finished stack may have a very large number of layers (e.g., 128 pairs of alternating oxide and nitride layers). However, initially forming all of these layers may result in a stack 224 with an aspect ratio that is too high to reliably form the narrow channel holes and other vias that penetrate the entire stack 224. Therefore, the stack 224 may be partially formed at first. A partial stack may then have the channel holes etched in the partial stack. Additional alternating oxide and nitride layers may be added on top of the partial stack, and those additional layers may be etched in the same location to form a channel hole that continues at a more uniform width through all of the alternating oxide and nitride layers, thus maintaining a high aspect ratio without excessive angling of the sidewalls of the channel holes.

FIG. 2B illustrates how the partial stack may be etched to form holes 203 that penetrate the alternating silicon oxide layers 206 and silicon nitride layers 208. The holes 203 may be formed by layering a mask over the partial stack and performing an etch process to remove material that is exposed by the mask. Any etch process may be used, and some embodiments may use a dielectric etch. Etching through the alternating silicon oxide layers 206 and silicon nitride layers 208 may benefit from a dielectric etch because the desired aspect ratio of the holes 203 for the device channels is relatively high (i.e., the vertical depth of the holes 203 is relatively large in comparison to the horizontal width of the holes 203). Generally, the depth of the holes 203 may be controlled based on the number of silicon oxide layers 206 and the number of silicon nitride layers 208 to be etched. For example, a time during which the etch process is allowed to run may be determined by the number of silicon oxide layers 206 and the number of silicon nitride layers 208 along the thicknesses of these layers. For example, some embodiments may etch the holes 203 down to the silicon nitride layer 204. Other embodiments may etch the holes 203 down to the silicon oxide layer 202, or down to the top of the substrate 200. The example illustrated in FIG. 2B stops the etch at the top of the silicon nitride layer 204.

FIG. 2C illustrates how a bottom-punch etch may be used to penetrate the substrate 200 to expose the silicon of the substrate 200, according to some embodiments. The dielectric etch used in FIG. 2B may stop the channel-hole etch before the etch penetrates the substrate 200. Some embodiments may then perform a second etch process such that the holes 203 extend down into the substrate 200. This additional etch may be a directional etch oriented vertically towards the bottom of the holes 203 may be referred to herein as a “bottom punch” etch. The bottom punch etch may allow the silicon material of the substrate 200 to be exposed at the bottom of the holes 203. The bottom punch etch may represent a separate etch from the etch used to form the holes. For example, the bottom punch etch may be performed in a conductor etch chamber instead of a dielectric etch chamber, which may have better critical dimension uniformity and profile tuning than the dielectric etch used to initially form the holes 203 for the device channels. The bottom punch may thus extend the holes 203 down into the substrate 200 to expose the silicon material. For example, the bottom punch etch may extend to the top surface of the substrate 200, or alternatively may penetrate into the substrate 200 below the top surface of the substrate 200. Alternatively, other embodiments may etch the entire length of the holes 203 down into the substrate 200 using a single etch process, thus combining the results of FIGS. 2B-2C into a single processing step. The exposed silicon material of the substrate 200 may be used in later steps to epitaxially grow silicon through the channels that form the 3D NAND flash memory cells.

FIG. 2D illustrates how the stack 224 may be extended by adding additional silicon oxide layers 207 and silicon nitride layers 209 on top of the partial stack, according to some embodiments. These additional layers may be formed incrementally on top of the partial stack. Alternatively, these layers may be formed separately and placed on top of the partial stack. It should be understood that the partial stack illustrated in these figures is greatly simplified for the sake of clarity. In practice, the stacks may include a large number of layers, a large number of channel holes, and may be used to form many hundreds of 3D NAND flash memory cells. However, these figures have been simplified to show the formation of a single epi silicon channel and the adjacent support structures or slits in the memory array. For example, an actual stack may include thousands of channels, more than 100 alternating oxide and nitride layers, and multiple slits and support structures. These layers may be formed in multiple processes, with etch operations performed incrementally on each batch of layers as they are added to the partial stack. Thus, although FIG. 2D illustrates only two partial stacks being combined, it should be understood that many additional partial stacks may be layered and etched to form the holes 203 through the stack 224. For example, some embodiments may include the combination of two partial stacks, each with approximately 128 alternating oxide-nitride layers for a total of 256 alternating oxide-nitride layers.

FIG. 2E illustrates a stack 224 formed from a plurality of partial stacks that are each etched individually, according to some embodiments. After adding the additional silicon oxide layers 207 and silicon nitride layers 209 of the second partial stack, holes 211, 219 may be etched in these layers as illustrated. Note that these holes 211, 219 may be formed using a similar mask as was previously used to etch the holes 203 in the first partial stack. By incrementally etching these layer sets, a very high aspect ratio may be achieved, despite the depth of the holes 211, 219 in the full stack 224.

FIG. 2F illustrates a support feature 210 that may be formed in one of the holes to provide support during the subsequent steps of the process, according to some embodiments. The support feature 210 may be selectively deposited in one of the holes in order to form a rigid structure. For example, some embodiments may use a metal, such as tungsten to form the support feature 210. Some embodiments may use a dielectric fill such as a SiOx or a metal-aluminum oxide-nitride-oxide-silicon (MANOS) stack for the support feature 210. Any deposition process may be used to form the support feature 210. Note that the support feature 210 may extend down into the substrate 200 by virtue of the etch process described above that over shoots the last silicon oxide layer 202. As will become apparent later in this disclosure, the support feature 210 keeps the layers of the stack 224 from collapsing when the sacrificial nitride layer 204 is removed. Furthermore, extending the support feature 210 down into the substrate 200 prevents any movement of the upper layers of the stack 224 when the nitride layer 204 is later removed.

FIG. 2G illustrates an initial layer of epitaxial silicon 212 formed in one of the holes 219, according to some embodiments. As mentioned above, the additional depth of the bottom punch etch into the substrate 200 exposes the silicon material of the substrate 200 to the channel hole 219. Because the single-crystal silicon of the substrate 200 is exposed, the layer of epitaxial silicon 212 may be grown in the channel hole using processes such as silicon epitaxial deposition or epitaxy that grows thin layers of single-crystal silicon over the single-crystal silicon substrate 200. For example, some embodiments may perform the epitaxy process through chemical vapor deposition. Materials such as silicon tetrachloride, trichlorosilane, dichlorosilane, silane, and other chemical sources of silicon may be provided to the deposition chamber to incrementally form the epitaxial silicon 212 that is grown on top of the substrate 200. The height of the epitaxial silicon 212 may be above the silicon oxide layer 202, but below the next silicon oxide layer in the stack 224. For example, the height of the epitaxial silicon 212 may be within the sacrificial nitride layer 204.

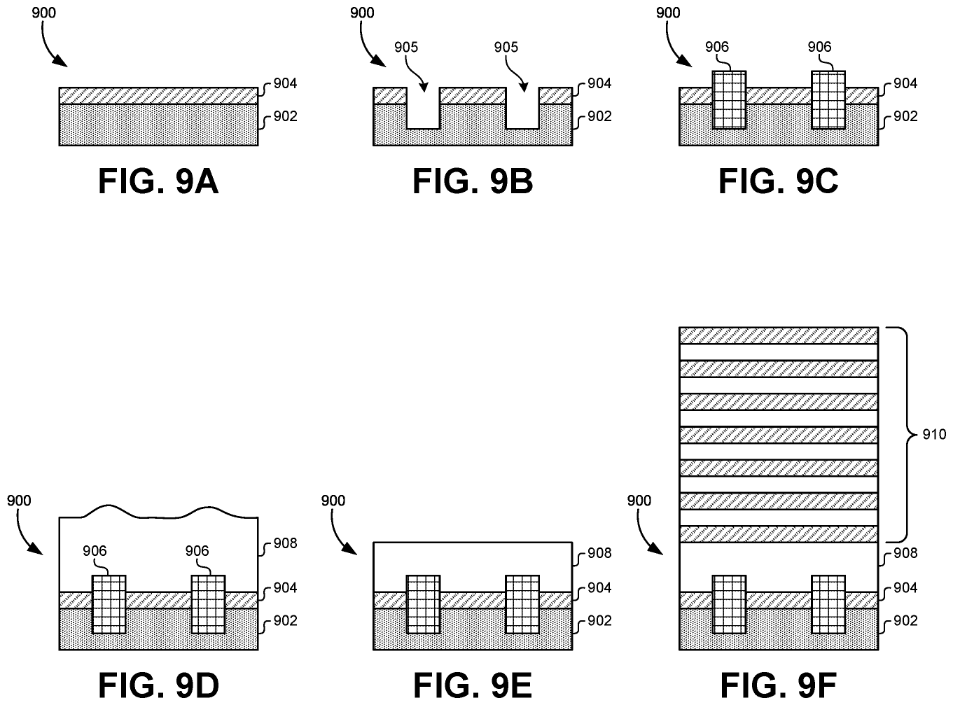

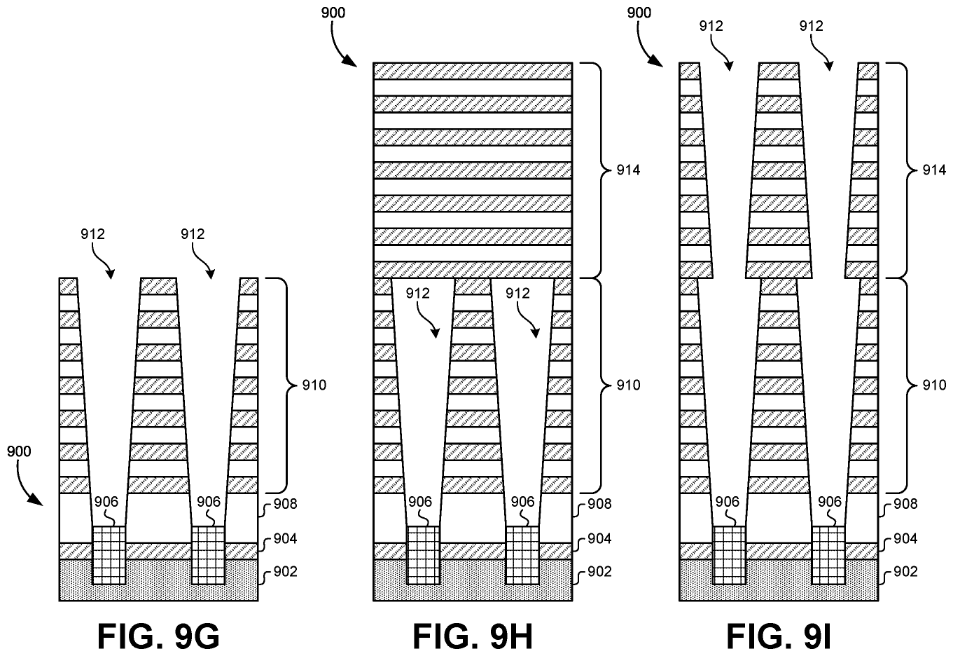

At this stage illustrated in FIG. 2G, the channel hole 219 has been formed in multiple tiers of alternating nitride/oxide layers such that the channel hole 219 extends down to expose the substrate 200. The epitaxial silicon 212 is then grown after the channel hole 219 has been formed in the device stack 224. However, alternate embodiments may instead first expose the silicon of the substrate 200 and form the epitaxial silicon 212 before forming the subsequent layers and etching the channel holes. This alternate process is described in detail below in FIGS. 9A-9I. This alternate process may be freely substituted in the place of the process described in FIGS. 2A-2G to form the same structure.

FIG. 211 illustrates the deposition of a tunneling layer 214 in the hole 219, according to some embodiments. Since the hole 219 may now be used to form a channel for a vertical column of 3D NAND memory cells, the hole 219 may also be referred to herein as a channel hole 219. The tunneling layer 214 may be formed by depositing a blocking dielectric or oxide, a charge trap nitride (e.g., silicon nitride), and a tunneling dielectric or oxide. These three layers may be collectively referred to as the “tunneling layer” 214 in this disclosure. The oxide layers in the tunneling layer 214 may provide an offset for the conduction band and the valence band for the transistor devices of the memory cells.

For example, a layer of silicon nitride may be enclosed within inner and outer layers of silicon oxide. The various layers of the tunneling layer 214 may be formed using atomic layer deposition, and thus the layers of the tunneling layer 214 may be relatively thin compared to the alternating oxide-nitride layers of the stack 224. This process may cause the tunneling layer 214 to grow on the sidewalls of the channel hole 219 and along the bottom of the channel hole over the top of the epitaxial silicon 212. Note that because the epitaxial silicon 212 stops before the alternating silicon oxide layers 206 and silicon nitride layers 208, the interior of the channel for the 3D NAND memory cells may be covered with the tunneling layer 214.

FIG. 2I illustrates how the channel hole 219 may be filled with a sacrificial gap fill material 216, according to some embodiments. In order to protect the tunneling layer 214 for subsequent etch processes, the channel hole 219 may be filled with a sacrificial gap fill material 216, such as carbon.

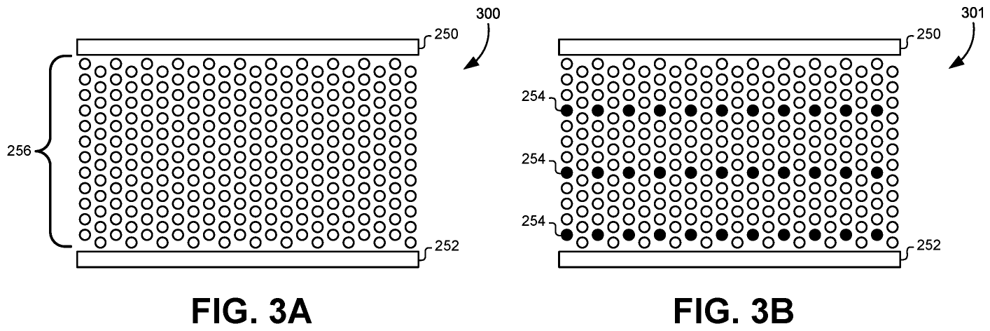

FIG. 2J illustrates a slit 218 that may be etched in the stack 224, according to some embodiments. The slit 218 may represent a relatively long trench that is etched in the stack 224 such that the slit 218 is adjacent to a plurality of individual channel holes along the length of the slit 218. See FIGS. 3A-3B below for an overhead view of the slit relative to the channel holes in the memory array. In contrast to the etch process used to form the channel holes, the slit 218 may be etched using a single process that penetrates all the layers of the stack 224. A single process may be used because the slit 218 may be wider than the channel holes. Therefore, the aspect ratio may be less, and therefore achievable in a single process. In some embodiments, a carbon liner 220 may be deposited on the interior of the slit 218 to protect the internal silicon oxide layers 206 and silicon nitride layers 208 from subsequent chemical etch processes that use the slit 218. For example, the carbon liner 220 may be deposited on the sidewalls and bottom of the slit 218, and a subsequent etch may be used to remove the carbon liner 220 from the bottom of the slit 218 to expose the silicon nitride layer 204. The slit 218 may be used in the memory array two separate different memory blocks. In later processes, the slit 218 may also provide access to all of the nitride layers in the stack 224 such that these nitride layers can be removed and replaced with tungsten (or any other conductive material) to form conductive pathways for each of the memory cells. These conductive pathways may later form the word lines or gate electrodes for the memory cells. For example, a wet etched using hot phosphoric acid may be used to remove the nitride layers from the stack 224, and the slit 218 may then provide access for the precursors such that an atomic layer deposition process may be used to grow the tungsten in the voids left behind from the removed nitride layers.

FIG. 2K illustrates the selective removal of the nitride layer 204, according to some embodiments. In order to grow the epitaxial silicon 212 in the channel holes, the nitride layer 204 may be removed in order to expose the portion of the tunneling layer 214 that needs to be removed such that the epitaxial silicon 212 may again be exposed to the channel holes. In this example, a wet etch may be used, such as a hot phosphoric acid chemical etch. The wet etch may access the nitride layer 204 through the slit 218 and remove the nitride layer 204 selectively. The carbon liner 212 may protect the internal nitride layers from the etch process. Other embodiments may use dry etches or other processes that are configured to selectively remove the nitride layer 204.

FIG. 2L illustrates the selective removal of the tunneling layer 214 from the bottom of the channel holes, according to some embodiments. Removal of the nitride layer of the tunneling layer 214 may use the wet/dry etch process described above. Similar processes may be used to selectively remove the dielectric or oxide layers of the tunneling layer 214. Note that the gap 230 left behind from the removal of the nitride layer 204 is lined on the top and bottom by oxide layers. These oxide layers (e.g., oxide layer 202) may be formed such that they are slightly thicker than the other oxide layers in the stack 224. However, because the oxide and nitride layers in the tunneling layer 214 may be formed as atomic layer deposition layers, these layers will be relatively thin, such that they can be removed without removing a significant portion of the other oxide layers that may be exposed to the etch process.

FIG. 2M illustrates the removal of the sacrificial gap fill material 216 from the channel hole 219, according to some embodiments. Note that removal of the sacrificial gap fill material 216 leaves the channel hole 219 lined by the tunneling layer 214 and exposed to the epitaxial silicon 212.

FIG. 2N illustrates the growth of the epitaxial silicon 212, according to some embodiments. The epitaxy process may be executed as described above. However, because the slit 218 and the channel hole 219 are exposed to the epitaxial silicon 212, a layer of epitaxial silicon 236 may be grown to fill the gap 230 and begin to fill the channel hole 219. The growth of the layer of epitaxial silicon 236 may stop when the bottom of the channel hole 219 is reached in order to prevent the slit 218 from also being filled with epitaxial silicon.

FIG. 2O illustrates the selective removal of a portion of the layer of epitaxial silicon 236 at the bottom of the slit 218. The portion of the layer of epitaxial silicon 236 may be removed using an etch process to perform a bottom “punch” as described above. This etch may remove the portion of the layer of epitaxial silicon 236 until the bottom oxide layer 202 as shown in FIG. 2O, or alternatively the etch may go below the bottom oxide layer 202 into the substrate 200.

FIG. 2P illustrates the deposition of a sacrificial gap fill material 240 in the slit 218, according to some embodiments. The sacrificial gap fill material 214 may be deposited in the slit 218 such that the epitaxial silicon layer 236 may be grown in the channel hole 219 without filling the slit 218.

FIG. 2Q illustrates the epitaxial growth of the epitaxial silicon layer 236 up through the channel hole 219, according to some embodiments. Until this point, the previous steps in this process have been performed in order to provide a channel hole in which epitaxial silicon can be grown as a channel core for the 3D NAND flash memory cells. For example, the steps described above provide a reference layer of epitaxial silicon at the bottom of the channel hole 219 grown from the substrate 200 itself. An epitaxy process may be carried out as described above to grow the epitaxial silicon layer 236 up through the channel hole 219. The resulting structure may include a stack 224 with a channel hole that is filled with an epitaxial silicon core 242 rather than oxide core or polysilicon core as is found in the traditional “Macaroni” structure of 3D NAND flash memory cells. Therefore, the embodiments described herein may be distinguished at least in part from traditional 3D NAND flash memory cells by the epitaxial silicon core 242 used for the channel, along with the physical connection between the epitaxial silicon core 242 and the substrate 200 and the angled walls of the channels and channel holes.

Referring to FIG. 2Q, a 3D NAND memory structure may include a silicon substrate 200, which may be formed with a single-crystal silicon. The memory structure may also include a plurality of alternating material layers 275 arranged in a vertical stack on the silicon substrate 200. The alternating material layers 275 may include alternating layers of an oxide material and a nitride material (e.g., silicon oxide and silicon nitride). At later stages in the manufacturing process, the alternating material layers 275 may instead include alternating layers of an oxide material and a metal, such as tungsten. For example, the nitride material may be selectively removed and replaced with the metal to form the gate electrodes for individual memory cells in the memory structure.

The alternating material layers 275 may define a channel hole 277 that extends through the plurality of alternating material layers 275 to the silicon substrate 200. This channel hole 277 may be formed using any of the processes described throughout this disclosure. As illustrated, the channel hole 277 may be approximately perpendicular to the plurality of alternating material layers 275. The memory structure may also include a channel inside the channel hole 277. The channel may include a tunneling layer 214 around the interior of the channel hole (and consequently around the exterior of the channel) using the layers described above. The channel may also include an epitaxial silicon core 242 inside the tunneling layer that contacts the silicon substrate 200. In some cases, the epitaxial silicon core 242 may extend into the silicon substrate 200, such that the epitaxial silicon core 242 begins its epitaxial growth below the top level of the silicon substrate 200.

The memory structure may also include a layer of epitaxial silicon 236 that extends beyond the channel hole, where the layer of epitaxial silicon 236 may be parallel to the plurality of alternating material layers 275. Recall that FIG. 2Q shows only one channel of many channels in the memory structure. Therefore, the layer of epitaxial silicon 236 may connect the epitaxial silicon core 242 of the illustrated channel to a plurality of other channels in the memory structure. For example, the epitaxial silicon cores of each channel connected by the layer of epitaxial silicon 236 may be grown simultaneously during the same epitaxy process from the layer of epitaxial silicon 236.

The process described above may be used to selectively grow the epitaxial silicon core 242 using the single-crystal silicon of the substrate 200. The 3D NAND flash memory cells that use an epitaxial silicon core 242 exhibit better performance than similar memory cells using oxide cores. For example, the mobility of polysilicon is 10 to 20 times less than the mobility of epitaxial silicon.

Further processes may be later be performed on the stack 224 to complete the memory array. Although these operations are beyond the scope of this disclosure, they may include removing the sacrificial gap fill material 240 from the slit, removing the nitride layers in the stack 224, depositing conductive metal (e.g., tungsten) in place of the nitride layers to form the gate electrodes, performing a staircase etch on the stack, and so forth.

FIG. 3A illustrates a portion of a memory array 300, according to some embodiments. This portion of the memory array 300 may represent a single memory block with offset rows of channels 256. Slits 250, 252 may be used to separate this memory block from other memory blocks. This example uses 24 channels into offset columns between the slits 250, 252. This portion of the memory array 300 may use traditional oxide or polysilicon cores for the channels. Therefore, no support structures may be needed, and each of the channel holes may be used to implement memory cells.

In comparison, FIG. 3B illustrates a portion of a memory array 301 when the some of the channels have been used for support structures to facilitate the epitaxial silicon channel cores, according to some embodiments. As described above, the process for growing the epitaxial silicon channels for memory cells in the memory array 301 may use a process where some of the channel holes are used for support structures 254 to prevent the memory array 301 from collapsing when the sacrificial nitride layer is removed to make room for the epitaxial silicon layer. These support structures 254 may be spaced throughout the memory array in order to provide adequate support for the layer stack in the array during the manufacturing process. Note that the spacing illustrated in FIG. 3B is provided only by way of example and is not meant to be limiting. In this example, the spacing of the support structures 254 is about every four channel holes and every other column. This configuration does slightly reduce the bit density per area in the memory array 301 by using some of the channel holes for support structures 254 that would otherwise be used for memory cells.

As described above, some embodiments may use channel holes in order to provide support structures during the manufacturing process. An advantage of using channel holes for support structures includes the ability to increase or decrease the spacing of the support structures as needed. However, some embodiments may instead form the same epitaxial silicon channels by using the slits instead of the channel holes to provide the support structures. These embodiments trade off the amount support provided across the memory block in exchange for an increase in the channel density.

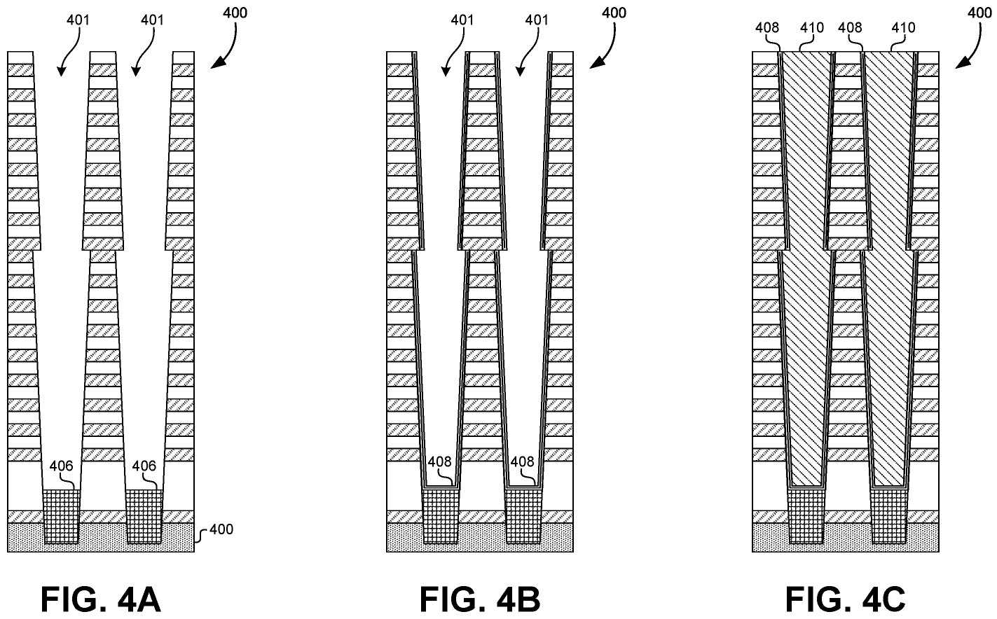

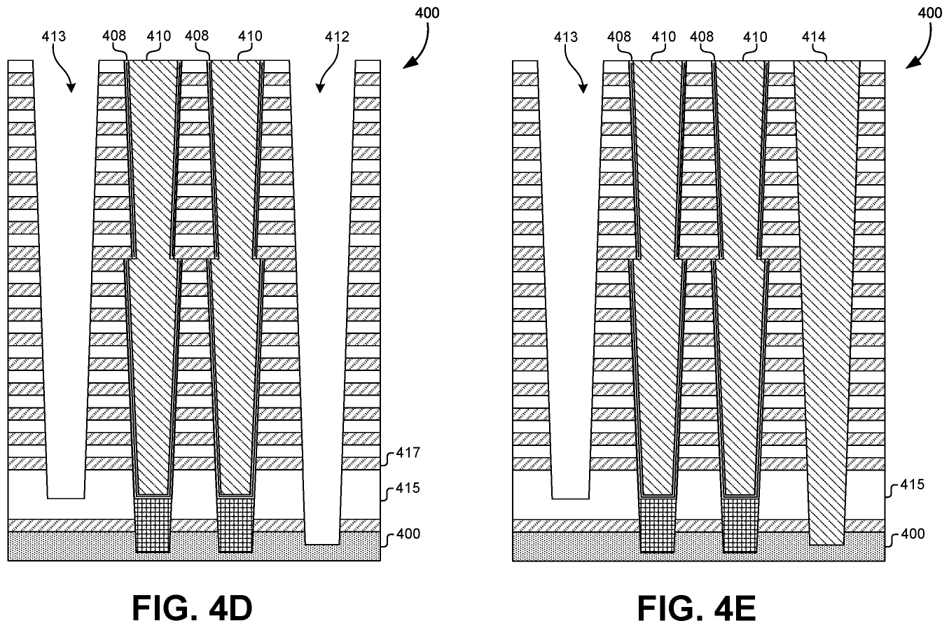

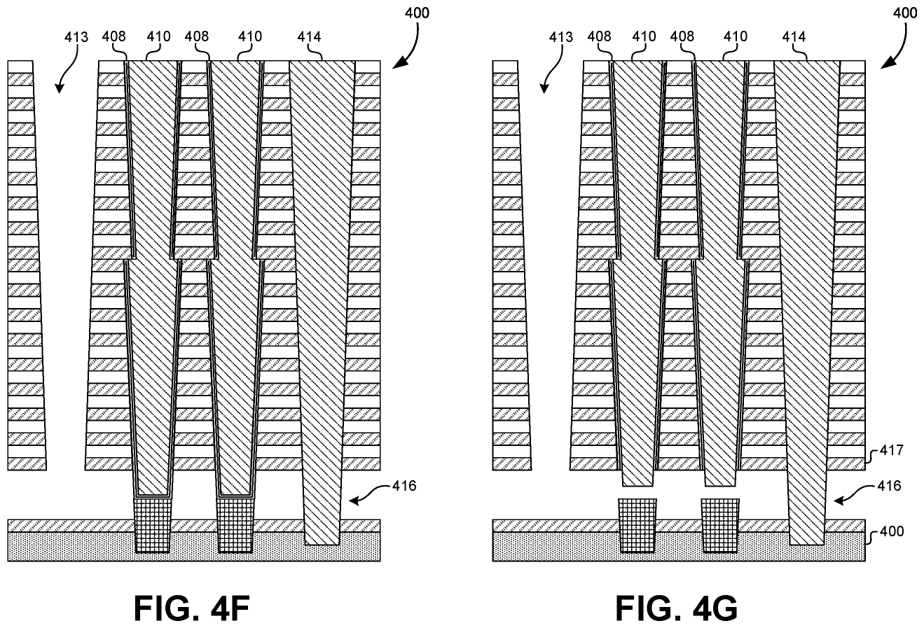

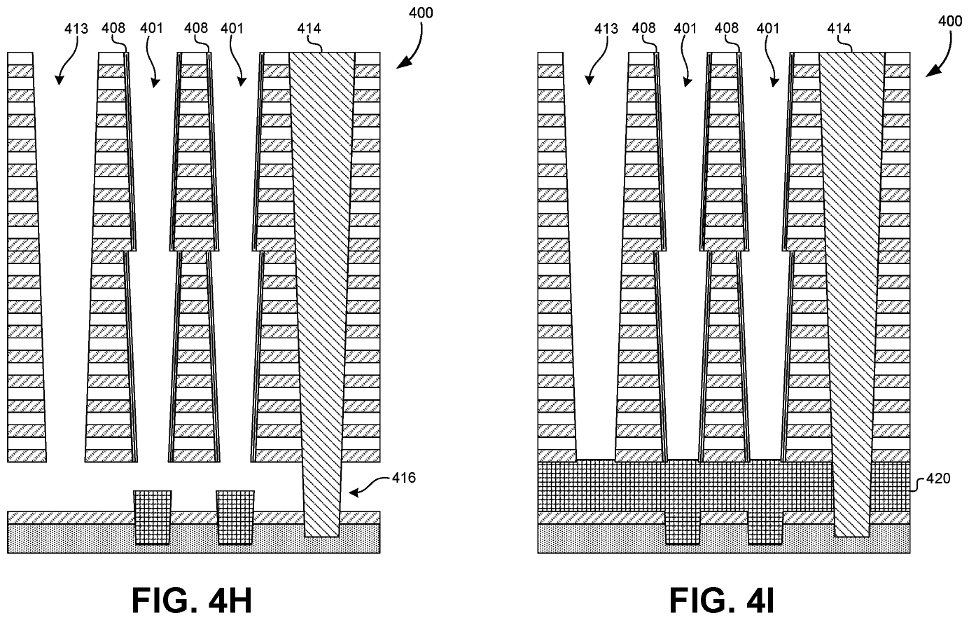

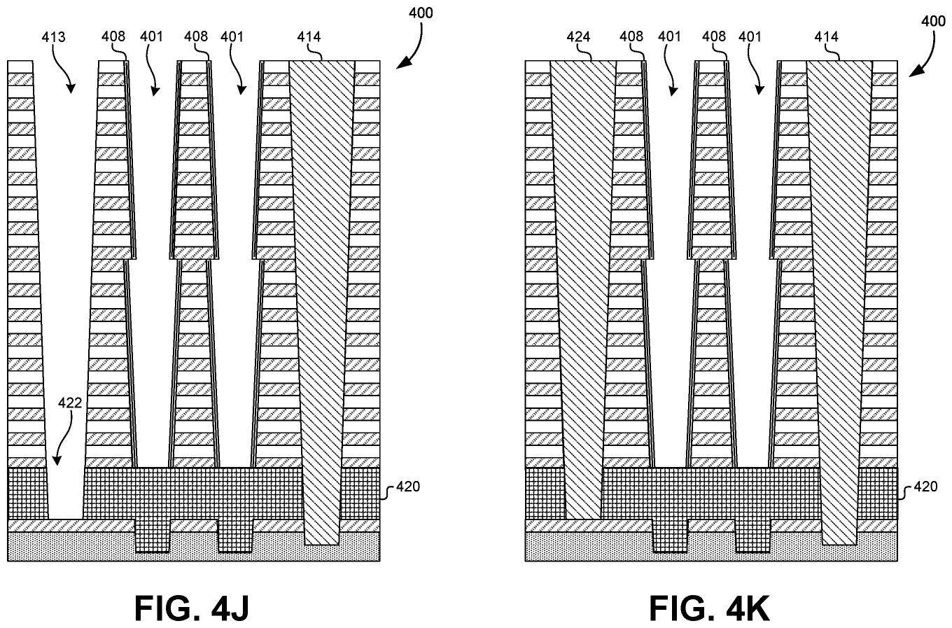

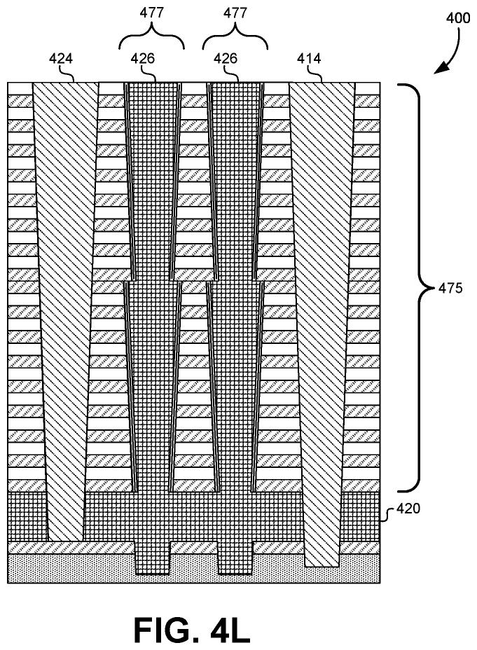

FIGS. 4A-4L illustrate incremental steps in a fabrication process for a memory structure that use the slits that separate the memory blocks for support structures when growing the epitaxial silicon channels for the individual memory cells, according to some embodiments. FIG. 4A illustrates channel holes 401 in a stack 400 that have epitaxial silicon 406 grown from the substrate 400, according to some embodiments. The channel holes 401 and the epitaxial silicon 406 may be formed using the process described above in relation to FIGS. 2A-2G. In some embodiments, the epitaxial silicon 406 may be formed after the channel holes 401 are formed in the first set of oxide/nitride layers and before the upper sets of oxide/nitride layers are formed and etched to extend the channel holes 401. For example, turning back to FIG. 2C, after the channel holes 203 have been etched and the bottom punch etch has been used to extend the channel holes 203 into the substrate 200, the epitaxial silicon 406 may be grown in the channel holes 203 at this stage from the exposed substrate 200. After the epitaxial silicon 406 has been formed in the holes 203, the upper alternating layers of oxide 207 and nitride 209 may be added and etched to increase the number of device layers and the depth of the channel holes 203, to eventually form the structure illustrated in FIG. 4A. Alternatively, the epitaxial silicon 406 may be grown after the channel holes 401 have been completely formed, or at any stage after the silicon of the substrate 400 has been exposed.

In this example, instead of using one of the channel holes 401 for a support structure, each of the channel holes 401 may instead be used to form channels for memory cells. FIG. 4B illustrates the channel holes 401 after being lined with a tunneling layer 408. The tunneling layer may be formed as described in detail above in relation to FIG. 2H. FIG. 4C illustrates the channel holes 401 filled with a sacrificial gap fill material 410, which may be formed as described in detail above in relation to FIG. 2I.

FIG. 4D illustrates slits 412, 413 that may be formed on either side of the memory block, according to some embodiments. It should be understood that although only two channel holes are illustrated in FIG. 4D, many additional channels may also be present between the slits 412, 413. For example, the slits 412, 413 may enclose a memory block with a block width of 24 channels. These channels may be arranged in a honeycomb pattern of two offset rows of 12 channels each. Multiple pairs of these offset rows of 24 channels may be present in the block. Typically, the slits 412, 413 are only etched to a depth that is above the substrate 400 but below the first oxide layer 417 in the alternating material layers that form the memory cells. For example, slit 213 is etched to a depth below the first oxide level 417 and within the sacrificial nitride layer 415. However, in order to provide a support structure when later fabricating the epitaxial silicon layer and channel cores, a slit may undergo an additional or extended etch process to increase the depth of the slit. For example, slit 412 may be etched to a depth that is below the top of the substrate 400 using a bottom-punch etch. This allows the slit 412 to act as a support structure that is anchored to the substrate 400 instead of being allowed to float on top of the substrate.

FIG. 4E illustrates the slit 412 that is designated to act as a support structure filled with a gap fill material 414, according to some embodiments. In this example, alternating slits may be used as support structures in the memory array. Thus, slit 413 may remain at a shallower depth, while slit 412 may be etched to the depth below the substrate 400 and filled with the gap fill material 414, which may act as the support structure during the growth of the epitaxial silicon layer.

FIG. 4F illustrates the removal of the sacrificial nitride layer 415, according to some embodiments. As described above in relation to FIG. 2K, the sacrificial nitride layer 415 may be exposed to an etch process through the slit 413 to selectively remove the sacrificial nitride layer 415. Although not shown explicitly in FIG. 4F, the slit 413 may have a protective liner material (e.g., carbon) applied to the sidewalls of the slit 413 to prevent the etch process from removing the nitride layers from the alternating material layers that are later used to form the memory cells. An additional bottom-punch etch may be applied to remove the protective liner from the bottom of the slit 213 such that the sacrificial nitride layer 415 is exposed to the etch process.

FIG. 4G illustrates the removal of the tunneling layers 408 from the bottom portion of the channels, according to some embodiments. For example, the layers used in the tunneling layer 408 may be selectively removed by wet and/or dry etch processes as described above. After the removal of the exposed portions of the tunneling layers 408 at the bottom of the channel holes, the gap fill material 414 may provide a support structure for the stack 400 to keep the stack 400 from collapsing after exposing a gap 416 between the substrate 400 and the first oxide layer 417.

FIG. 411 illustrates the removal of the sacrificial gap fill material 410 from the channel holes 401 using a selective etch. FIG. 41 illustrates the epitaxial growth of a epitaxial silicon layer 420 in the gap 416. As described above, the epitaxial silicon layer 420 may be grown until it begins to fill the channel holes 401. FIG. 4J illustrates the formation of a hole 422 in the epitaxial silicon layer 420 to extend the slit 413 using a bottom-punch etch process. FIG. 4K illustrates the slit 413 filled with a gap fill material 424. FIG. 4L illustrates the growth of epitaxial silicon cores 426 in each of the channels in the memory block. Each of these steps may be carried out as described in detail above in relation to FIGS. 2A-2Q.

The channels in the resulting stack 400 illustrated in FIG. 4L may be substantially the same as the channels in the resulting stack 224 in FIG. 2Q, with alternating material layers 475 and channel holes 477 that are lined with tunneling layers 408 and filled with epitaxial silicon cores 426. However, in the memory structure that includes this stack 400, none of the channels need to be set aside as support structures. Instead the maximum channel density may be achieved by using the slits as support structures during the fabrication process. As described above, additional process steps that are beyond the scope of this disclosure may subsequently be performed on the stack 400 to complete the fabrication of the memory structure, such as removal of the alternating nitride layers, formation of conductive layers (e.g., tungsten layers) to form gate electrodes, execution of a staircase etch, and so forth.

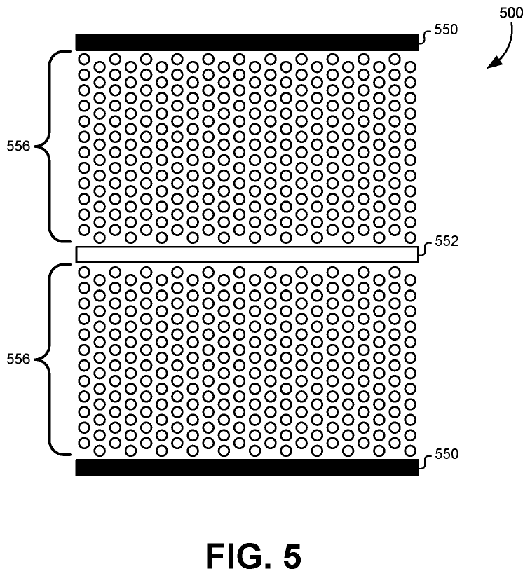

FIG. 5 illustrates a top view of a portion of a memory array 500, according to some embodiments. In this example, all of the channel holes 456 may be used to form channels for memory cells. Alternating slits 550 may be used to provide support structures during the fabrication process, while the remaining slits 552 may be used to provide access to the sacrificial nitride layer during the fabrication process as described above. Note that using alternating slits 550 is used only by way of example and is not meant to be limiting. Depending on the block width of each memory block, other embodiments may use every third slit, every fourth slit, and so forth, based on the number of channels in each block and the amount of support needed to prevent collapse.

Instead of using only channel holes for support structures or only slits for support structures, some embodiments may use a combination of slits and channel holes to provide support structures. This allows the spacing of the support structures to be extremely flexible. Using slits still minimizes the number of channel holes that are sacrificed for support structures, while still allowing a number of channel holes to provide additional support structures as needed.

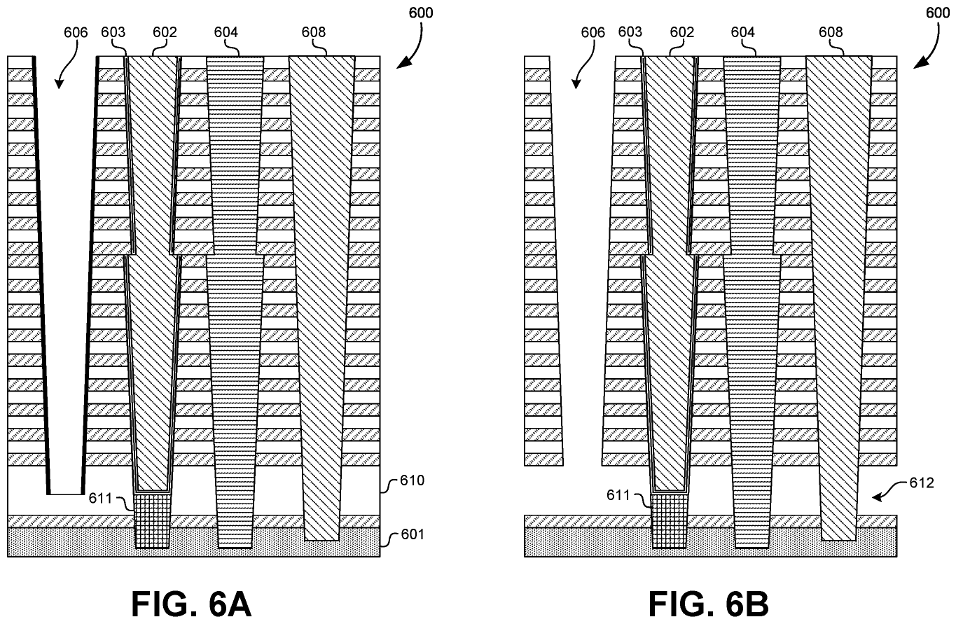

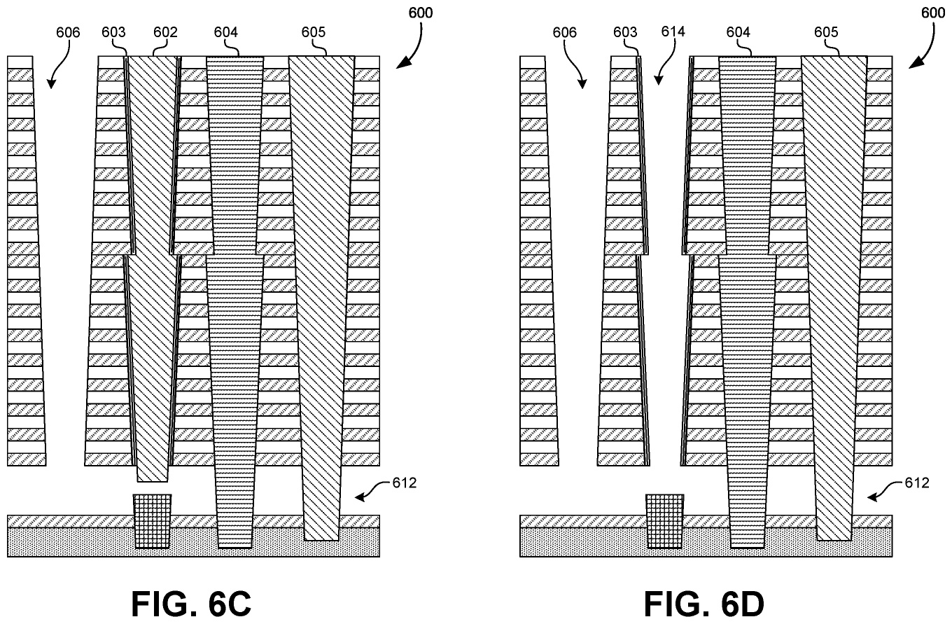

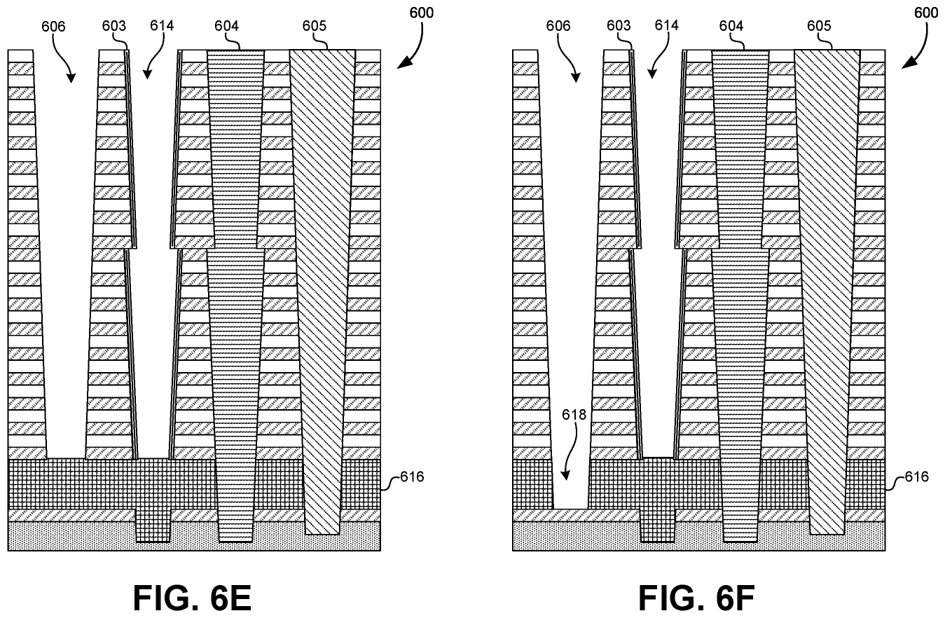

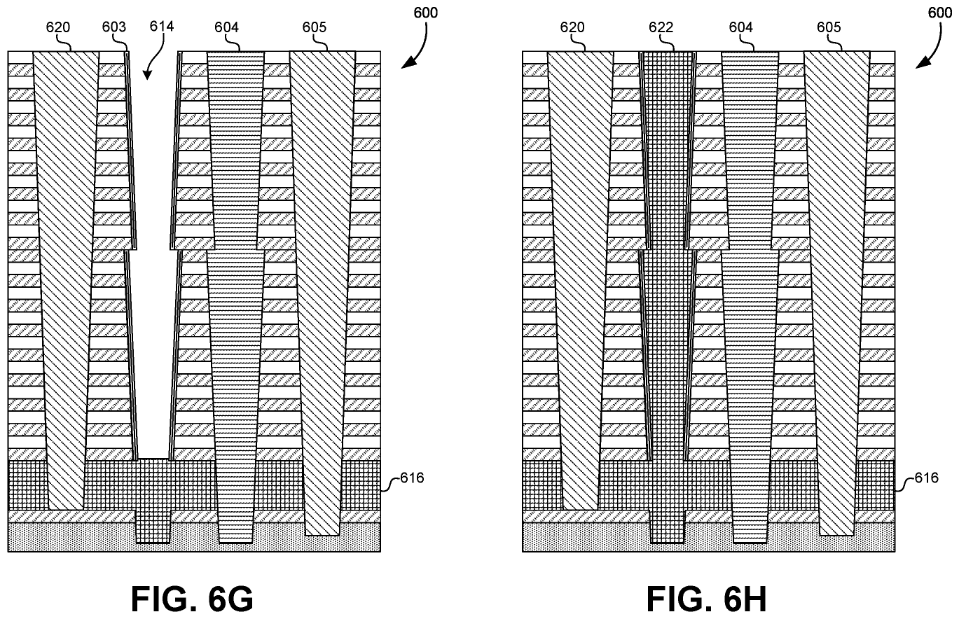

FIGS. 6A-6H illustrate incremental steps for forming a stack 600 that includes support structures in both channel holes and slits, according to some embodiments. FIG. 6A illustrates a stack 600 with a channel hole filled with a support structure 604. Additional channel holes with support structures may also be present in the stack 600 that are not explicitly shown in FIG. 6A. The stack 600 may also include a channel hole filled with a gap fill material 602 with a tunneling layer 603 that separates the gap fill material 602 from epitaxial silicon 611 that is grown from the substrate 601. Note that many additional channel holes may also be present in the stack 600 that are not visible in FIG. 6A. The stack 600 may also include a slit 606 with a liner that is etched down to a level above the substrate 601 and contacts the sacrificial nitride layer 610. Another slit may be filled with a gap fill material 608 and may extend down into the substrate 601 to act as a support structure.

The remaining steps to grow the epitaxial silicon into the channels of the stack 600 may be carried out as described in detail above. For example, FIG. 6B illustrates the removal of the sacrificial nitride layer 610 to expose a gap 612 while the stack 600 is supported by the support structures. FIG. 6C illustrates a removal of the portions of the tunneling layer 603 that are exposed in the gap 612. FIG. 6D illustrates the removal of the gap-fill material 602 in the channel hole 614. FIG. 6E illustrates the growth of an epitaxial silicon layer 616 in the gap 612. FIG. 6F illustrates the result of a bottom-punch etch to extend a hole 618 through the epitaxial silicon layer 616 for the slit 606. FIG. 6G illustrates a gap fill material 620 in the slit 606. FIG. 611 illustrates the growth of the epitaxial silicon core 622 in the channel hole 614.

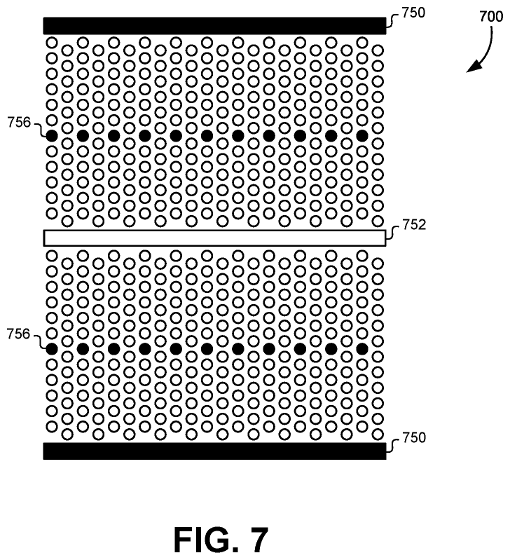

FIG. 7 illustrates a top view of a portion of a memory array 700, according to some embodiments. In this example, most of the channel holes may be used to form channels for memory cells. Alternating slits 750 may be used to provide support structures during the fabrication process, while the remaining slits 752 may be used to provide access to the sacrificial nitride layer during the fabrication process as described above. Instead of using only slits for support structures, this hybrid example uses a combination of slits and channel holes 756 to provide support structures as described. This allows the spacing of the support structures to be very configurable. Using slits minimizes the number of channel holes that are sacrificed for support structures, while still allowing a number of channel holes to provide additional support structures as needed.

As illustrated in this example, the processes described herein may be used to form a 3D NAND memory array 700 that includes a silicon substrate and a plurality of alternating material layers arranged in a vertical stack on the silicon substrate. A plurality of channel holes may extend through the alternating material layers. A plurality of support structures that extend through the plurality of alternating material layers into the silicon substrate may provide support during the fabrication of the memory array 700. The support structures may include a metal that fills one or more of the channel holes 756. The support structures may also include a gap fill material that fills slits 750 in the memory array 700. Some embodiments may use a combination of metal-filled channel holes and/or gap-fill material in one or more slits in any combination and without limitation.

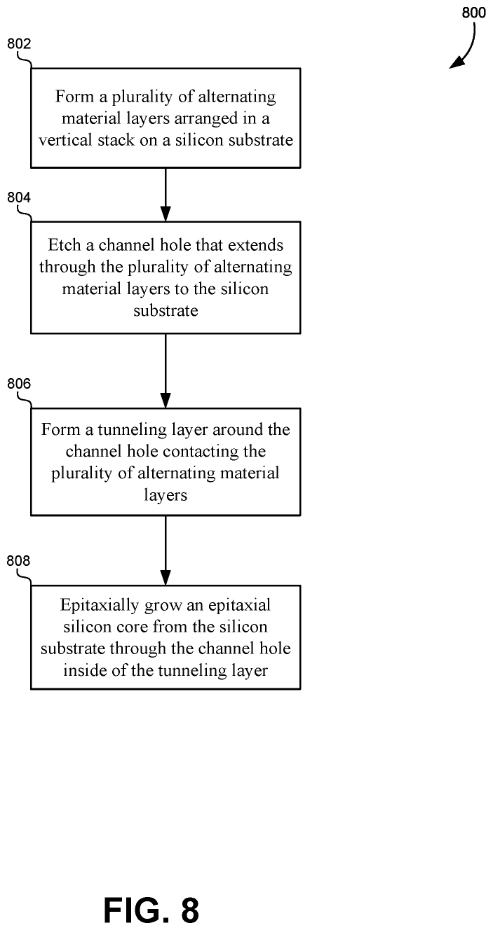

FIG. 8 illustrates a flowchart 800 of a method for fabricating a 3D NAND memory structure, according to some embodiments. This method may be executed in various processing chambers in a semiconductor processing system, as illustrated in FIG. 1. The method may include forming a plurality of alternating material layers arranged in a vertical stack on a silicon substrate (802). The alternating layers may include nitride and oxide layers formed in a stack as described above in FIGS. 2A-2E. The method may also include etching a channel hole that extends through the plurality of alternating material layers to the silicon substrate (804). The channel hole may be etched using a bottom-punch etch to penetrate the silicon substrate as described above in FIG. 2E.

The method may additionally include forming a tunneling layer around the channel hole contacting the plurality of alternating material layers (806). The tunneling layer in the channel hole may be formed as described above in FIGS. 2H-2L by depositing a tunneling oxide comprising the layers described above, and selectively removing a portion of the tunneling layer that is exposed to an etch process at the bottom of the channel.

The method may further include epitaxially growing a silicon core from the silicon substrate through the channel hole inside of the tunneling layer (808). The epitaxial silicon core may be grown using the steps described throughout this disclosure. For example, growing the epitaxial silicon core may include etching a slit in the memory structure that extends through the plurality of alternating material layers into a sacrificial nitride layer that is above the silicon substrate as illustrated in FIG. 2J. The sacrificial nitride layer may be exposed to an etch process that is configured to selectively etch the sacrificial nitride layer as illustrated in FIG. 2K-2M. An epitaxial silicon layer may be epitaxially grown from the silicon substrate to replace the sacrificial nitride layer as illustrated in FIG. 2N. In some embodiments, a support structure may be formed by etching a second channel hole that extends through the plurality of alternating material layers into the silicon substrate and filling the second channel hole with a gap fill material as a support structure.

It should be appreciated that the specific steps illustrated in FIG. 8 provide particular methods of fabricating a 3D NAND memory structure according to various embodiments. Other sequences of steps may also be performed according to alternative embodiments. For example, alternative embodiments may perform the steps outlined above in a different order. Moreover, the individual steps illustrated in FIG. 8 may include multiple sub-steps that may be performed in various sequences as appropriate to the individual step. Furthermore, additional steps may be added or removed depending on the particular applications. Many variations, modifications, and alternatives also fall within the scope of this disclosure.

In the embodiments described above, at least a portion of the channel holes were first formed in the alternating nitride/oxide layers down to the substrate before the epitaxial silicon was formed at the bottom of the channel holes. However, alternative methods may also be used for forming the epitaxial silicon at the bottom of the channel holes earlier in the manufacturing process.

FIGS. 9A-9I illustrate steps in a process for forming channel holes with epitaxial silicon at the base of the channel holes before the channel holes are formed in the tiers of alternating oxide/nitride layers, according to some embodiments. FIG. 9A illustrates a silicon substrate 902 that may be formed as described above. An oxide layer 904, such as a silicon oxide layer may be formed on top of the substrate 902.

FIG. 9B illustrates how a bottom portion of the channel holes 905 may be etched to the silicon substrate 902 prior to forming the subsequent oxide and/or nitride layers in the device stack. Any etch process may be used to form the bottom portion of the channel holes 905 since the aspect ratio is so low. For example, a dielectric etch may be used to form the channel holes 905 instead of the bottom punch etch described above since the vertical depth of the channel holes 905 is so small. Although the bottom portion of the channel holes 905 are only shown in the oxide layer 904 and the substrate 902, other layers may also be present on top of the oxide layer 904 in other embodiments. As described in the alternate processes above, the bottom portion of the channel holes 905 may be etched to a depth that exposes the silicon of the substrate 902. For example, the channel holes 905 may be etched at least to a top surface of the substrate 902, or may be etched to below the top surface of the substrate 902 such that the bottom portion of the channel holes 905 penetrates into the substrate 902.

FIG. 9C illustrates how the epitaxial silicon 906 may be formed in the bottom portion of the channel holes 905. The epitaxial silicon 906 may be grown epitaxially from the crystal structure of the exposed silicon of the substrate 902. The epitaxial silicon 906 may be grown until it is above a top surface of the substrate 902, or may be grown until is above the top surface of the oxide layer 904. Although the epitaxial silicon 906 is shown as a rectangular shape growing straight up from the sides of the channel holes 905 for the sake of clarity, actual implementations may begin to expand as the epitaxial silicon 906 is no longer bounded by the channel holes 905. For example, the epitaxial silicon 906 may form a “mushroom” shape as it grows past the top surface of the oxide layer 904. This horizontal expansion is allowable since there will still be a considerable separation between adjacent channel holes in the device layout.

FIG. 9D illustrates how the bottom nitride layer 908 may be formed over the epitaxial silicon 906. As described above, the bottom nitride layer 908 may be thicker than the other nitride layers in the device stack. The bottom nitride layer 908 may be formed on top of the oxide layer 904 and the epitaxial silicon 906 using any of the processes described above. However, because the epitaxial silicon 906 may be grown above the top surface of the oxide layer 904, the bottom nitride layer 908 may not form with a flat top surface. As illustrated in FIG. 9D, the bottom nitride layer 908 may conform to the shape and contours of the epitaxial silicon 906 as it protrudes above the top of the oxide layer 904. Thus, the top of the bottom nitride layer 908 may have an uneven surface after it is formed.

FIG. 9E illustrates how the bottom nitride layer 908 may be processed to planarize the top surface of the nitride layer 908. For example, a polishing process, such as a chemical-mechanical polishing process may be used to planarize the top surface of the wafer after the bottom nitride layer 908 is formed. This polishing process may remove a portion of the bottom nitride layer 908 until the top surface of the bottom nitride layer 908 is substantially flat. Flattening the bottom nitride layer 908 may provide a flat and stable surface on which the remaining alternating nitride/oxide layers in the device stack may be formed.

FIG. 9F illustrates how the alternating layers of nitrate/oxide 910 may be formed on top of the bottom nitride layer 908. These alternating layers of nitrate/oxide 910 may be formed using any of the processes described above. FIG. 9F illustrates a single tier of alternating layers of nitrate/oxide 910 formed on top of the bottom nitride layer 908. Additional tiers may be formed on top of this first tier after the channel holes have been etched.

FIG. 9G illustrates how the channel holes 912 may be etched in the alternating layers of nitride/oxide 910. Instead of etching the channel holes 912 down into the silicon substrate 902, this etch process only needs to etch down to the top of the epitaxial silicon 906. The channel holes 912 may be etched using a dielectric etch. Therefore, this process may eliminate the need to transfer the wafer to a conductor etch chamber to perform the bottom punch etch to extend the channel holes 912 down into the silicon substrate 902. By forming the epitaxial silicon 906 earlier in the process before the alternating layers of nitride/oxide 910 are formed, the depth of the channel hole etch may be reduced, resulting in a simplified etch process.

FIG. 9H illustrates how a subsequent tier of alternating layers of nitride/oxide 914 may be formed on top of the first tier of alternating layers of nitride/oxide 910. FIG. 9I illustrates how the alternating layers of nitride/oxide 914 in the second tier may then be etched to extend the channel holes 912 down to the alternating layers of nitride/oxide 910 in the first tier.

This alternative process illustrated in FIGS. 9A-9I may be freely substituted for the process illustrated above in FIGS. 2A-2G to form the with the epitaxial silicon at the bottom of the channel holes.

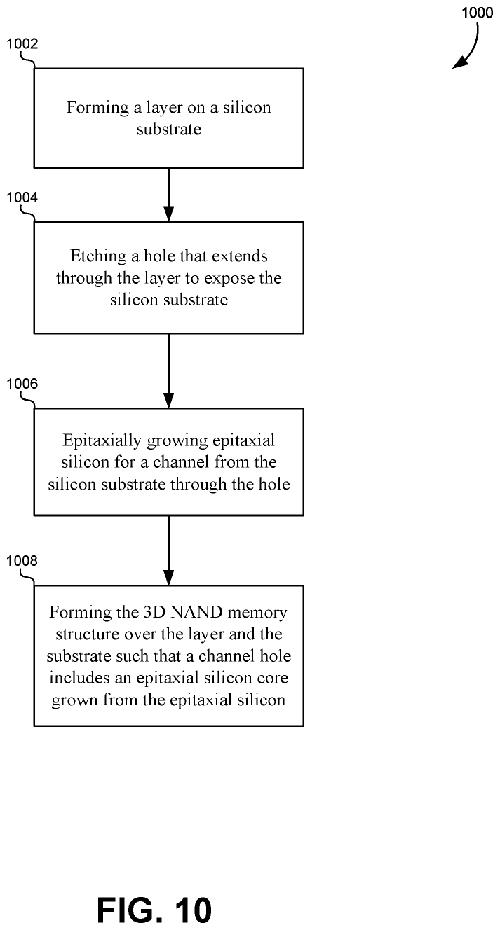

FIG. 10 illustrates a flowchart 1000 of a method for fabricating a 3D NAND memory structure, according to some embodiments. This method may be performed as part of the method described above and illustrated in FIG. 8 in order to form the initial epitaxial silicon used to grow the epitaxial silicon core for the device. For example, in step 804, the channel hole may be etched through the plurality of alternating material layers down to the epitaxial silicon formed using the method of flowchart 1000 instead of etching all the way down to the silicon substrate.

The method may include forming a layer on a silicon substrate (1002). The silicon substrate may be formed from any of the silicon materials described above. The layer may include an initial oxide layer, such as a silicon oxide layer. The method may also include etching a hole that extends through the layer to expose the silicon substrate (1004). A pattern may be introduced onto the layer that corresponds to locations for channel holes in the 3D NAND memory structure. As described above, this hole may be etched down to expose the silicon substrate. For example, the hole may be etched to expose a top surface of the silicon substrate, or the hole may be etched to penetrate below the top surface of the silicon substrate. This etch may be performed using a conductor etch process, a dielectric etch process, or any other type of etch process.

The method may further include epitaxially growing epitaxial silicon for a channel from the silicon substrate through the hole (1006). The epitaxial silicon may form a silicon plug that fills the hole in the silicon substrate and the layer. In some embodiments, the epitaxial silicon may be grown to a level above the top surface of the semiconductor substrate but below the top surface of the layer. The epitaxial silicon may also be grown above the top surface of the layer such that the top of the epitaxial silicon is higher than the top of the layer.

The method may additionally include forming the 3D NAND memory structure over the layer and the substrate such that a channel hole in the 3D NAND memory structure comprises an epitaxial silicon core grown from the epitaxial silicon (1008). For example, a bottom nitride layer, such as a silicon nitride layer, may be formed over the layer and the epitaxial silicon. The top of this nitride layer may not be smooth, and instead may have a surface contour that in influenced by the height difference between the layer and the epitaxial silicon beneath. This nitride layer may then be subjected to a polishing process to planarize the top of the nitride layer to create a smooth surface for growing subsequent device layers. The method may then include forming a plurality of alternating material layers, such as alternating nitride and oxide layers on top of the substrate and the layer. A channel hole may then be etched through the plurality of alternating nitride and oxide layers to expose the epitaxial silicon beneath. This epitaxial silicon may then be used to epitaxially grow the epitaxial silicon core of through the channel hole.

It should be appreciated that the specific steps illustrated in FIG. 10 provide particular methods of fabricating a 3D NAND memory structure according to various embodiments. Other sequences of steps may also be performed according to alternative embodiments. For example, alternative embodiments may perform the steps outlined above in a different order. Moreover, the individual steps illustrated in FIG. 10 may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A three-dimensional (3D) NAND memory structure comprising:
a layer on a silicon substrate;
an oxide layer over the silicon substrate, wherein a hole is etched through the oxide layer to expose the silicon substrate;
epitaxial silicon that is grown from the substrate through the hole in the oxide layer; and
a nitride layer that covers the oxide layer and the epitaxial silicon.

2. The 3D NAND memory structure of claim 1, wherein the epitaxial silicon extends above a top surface of the oxide layer.

3. The 3D NAND memory structure of claim 1, wherein a top surface of the nitride layer is planarized such that the top surface of the nitride layer is flat without surface variations caused by a difference in height between the oxide layer and the epitaxial silicon.

4. The 3D NAND memory structure of claim 1, wherein the hole extends below a top surface of the silicon substrate such that the epitaxial silicon extends into the silicon substrate.

5. The 3D NAND memory structure of claim 1, further comprising:
a plurality of alternating material layers arranged in a vertical stack on the nitride layer.

6. The 3D NAND memory structure of claim 5, further comprising:
a channel hole that extends through the plurality of alternating material layers to the epitaxial silicon.

7. The 3D NAND memory structure of claim 6, further comprising:
a channel inside the channel hole, wherein the channel comprises:
a tunneling layer around an interior of the channel hole contacting the plurality of alternating material layers; and
an epitaxial silicon core inside the tunneling layer that contacts and is grown from the epitaxial silicon.

8. The 3D NAND memory structure of claim 1, wherein the silicon substrate comprises a single-crystal silicon from which the epitaxial silicon is grown.

9. The 3D NAND memory structure of claim 1, further comprising a plurality of alternating material layers arranged in a vertical stack on the nitride layer and comprising alternating layers of an oxide material and a metal, wherein the metal forms a gate electrode for individual memory cells in the memory structure.

10. The 3D NAND memory structure of claim 9, further comprising:
a layer of epitaxial silicon that extends beyond a channel hole, wherein the layer of epitaxial silicon is between the silicon substrate and the plurality of alternating material layers, and the layer of epitaxial silicon connects the epitaxial silicon core to a plurality of other channels in the memory structure.

11. The 3D NAND memory structure of claim 10, further comprising:
a support structure that extends through the plurality of alternating material layers and the layer of epitaxial silicon and extends into the silicon substrate.

12. A method of fabricating a three-dimensional (3D) NAND memory structure, the method comprising:
forming a layer on a silicon substrate;
etching a hole that extends through the layer to expose the silicon substrate;
epitaxially growing epitaxial silicon for a channel from the silicon substrate through the hole; and
forming the 3D NAND memory structure over the layer and the substrate such that a channel hole in the 3D NAND memory structure comprises an epitaxial silicon core grown from the epitaxial silicon.

13. The method of claim 12, wherein the epitaxial silicon is grown above a top surface of the layer.

14. The method of claim 12, wherein the layer comprises a silicon oxide layer.

15. The method of claim 12, wherein forming the 3D NAND memory structure over the layer and the substrate comprises:
forming a nitride layer over the layer and the epitaxial silicon.

16. The method of claim 15, wherein forming the 3D NAND memory structure over the layer and the substrate further comprises:
polishing the nitride layer to remove surface variations caused by a difference in height between the layer and the epitaxial silicon.

17. The method of claim 12, wherein forming the 3D NAND memory structure over the layer and the substrate comprises:
forming a plurality of alternating nitride and oxide layers over the layer and the substrate.

18. The method of claim 17, wherein forming the 3D NAND memory structure over the layer and the substrate further comprises:
etching a channel hole through the plurality of alternating nitride and oxide layers to expose the epitaxial silicon; and
epitaxially growing the epitaxial silicon up through the channel hole to form the epitaxial silicon core of the channel hole.

19. The method of claim 12, wherein forming the 3D NAND memory structure over the layer and the substrate comprises:
forming a plurality of alternating material layers arranged in a vertical stack on a silicon substrate;
etching a channel hole that extends through the plurality of alternating material layers to the epitaxial silicon;
forming a tunneling layer around the channel hole contacting the plurality of alternating material layers; and
epitaxially growing an epitaxial silicon core from the epitaxial silicon through the channel hole inside of the tunneling layer.

20. The method of claim 19, further comprising:
etching a slit in the memory structure that extends through the plurality of alternating material layers into the layer;
exposing layer to an etch process that is configured to selectively etch the layer;
removing a portion of the tunneling layer that is exposed after removing the layer.
